(19) United States
(12) Patent Application Publication
(10) Pub. No.: US 2022/0336205 A1
(43) Pub. Date: Oct. 20, 2022

(54) FILM FORMATION METHOD

(71) Applicant: Tokyo Electron Limited, Minato-ku, Tokyo (JP)

(72) Inventors: Kenji OUCHI, Nirasaki-shi, Yamanashi (JP); Shuji AZUMO, Nirasaki-shi, Yamanashi (JP); Yumiko KAWANO, Nirasaki-shi, Yamanashi (JP); Shinichi IKE, Nirasaki-shi, Yamanashi (JP)

(21) Appl. No.: 17/753,490

(22) PCT Filed: Aug. 24, 2020
(86) PCT No.: PCT/JP2020/031752

§ 371 Date: Mar. 4, 2022

(30) Foreign Application Priority Data
Sep. 5, 2019 (JP) 2019-162078
May 28, 2020 (JP) 2020-092874

(51) Int. Cl. H01L 21/02; C23C 16/455; C23C 16/56; C23C 16/40; C23C 16/06

(52) U.S. Cl. CPC H01L 21/0234; H01L 21/02164; H01L 21/0228; C23C 16/45525; C23C 16/56; C23C 16/40; C23C 16/06

(57) ABSTRACT

A film formation method for selectively forming a film on a substrate includes: a preparation step of preparing a substrate having a surface on which a first film and a second film are exposed; a first film forming step of supplying a compound for forming a self-assembled monolayer onto the substrate to form the self-assembled monolayer on the first film, the compound having a functional group including fluorine and carbon and suppressing formation of a third film; a second film forming step of forming the third film on the second film; and a first removal step of removing the third film formed in a vicinity of the self-assembled monolayer by irradiating the surface of the substrate with ions or active species, wherein the third film is a film which forms a volatile compound more easily than the first film by being bonded to fluorine and carbon in the self-assembled monolayer.

### TECHNICAL FIELD

The present disclosure relates to a film formation method.

### BACKGROUND

In the manufacture of semiconductor devices, a photography technique is widely used as a technique for selectively forming a film in a specific region on the surface of a substrate. For example, an insulating film is formed after forming a lower layer wiring, a dual damascene structure having trenches and via holes is formed by photolithography and etching, and a conductive film such as a Cu film is embedded in the trenches and the via holes to form wirings.

However, in recent years, the miniaturization of semiconductor devices has been progressing more and more, and the positioning accuracy may not be sufficient in the photolithography technique.

Therefore, there is a demand for a method of selectively forming a film in a specific region on the surface of a substrate without using a photolithography technique. As such a technique, a technique for forming a self-assembled monolayer (SAM) in a region on the surface of a substrate for which a film formation is not desired has been proposed (see, e.g., Patent Documents 1 to 4 and Non-Patent Documents 1 to 4). Since a predetermined film is not formed in the region of the surface of the substrate in which the SAM is formed, it is possible to form the predetermined film only in the region of the surface of the substrate in which the SAM is not formed.

### PRIOR ART DOCUMENTS

### Patent Documents

Patent Document 1: Japanese National Publication of International Patent Application No. 2007-501902
Patent Document 2: Japanese National Publication of International Patent Application No. 2007-533156
Patent Document 3: Japanese National Publication of International Patent Application No. 2010-540773
Patent Document 4: Japanese National Publication of International Patent Application No. 2013-520028

### Non-Patent Documents

Non-Patent Document 1: G. S. Oehrlein, D. Metzler, and C. Li “Atomic Layer Etching at the Tipping Point: An Overview” ECS J. Solid State Sci. Technol. 2015 vol. 4 no. 6 N5041-N5053
Non-Patent Document 2: Ming Fang and Johnny C. Ho “Area-Selective Atomic Layer Deposition: Conformal Coating, Subnanometer Thickness Control, and Smart Positioning” ACS Nano, 2015, 9 (9), pp 8651-8654
Non-Patent Document 3: Adriaan J. M. Mackus, Marc J. M. Merkx, and Wilhelmus M. M. Kessels “From the Bottom-Up: Toward Area-Selective Atomic Layer Deposition with High Selectivity” Chem., 31 (1), pp 2-12
Non-Patent Document 4: Fatemeh Sadat Minaye Hashemi, Bradlee R. Birchansky, and Stacey F. Bent “Selective Deposition of Dielectrics: Limits and Advantages of Alkanethiol Blocking Agents on Metal-Dielectric Patterns on Metal-Dielectric Patterns” ACS 48), pp 33264-33272

The present disclosure provides some embodiments of a film formation method capable of improving the productivity of semiconductor devices manufactured using selective film formation.

### SUMMARY

According to one embodiment of the present disclosure, there is provided a method for a film formation method for selectively forming a film on a substrate that includes a preparation step, a first film forming step, a second film forming step, and a first removal step. In the preparation step, a substrate having a surface on which a first film and a second film are exposed is prepared. In the first film forming step, a compound for forming a self-assembled monolayer is supplied onto the substrate, whereby a self-assembled monolayer is formed on the first film. The compound has a functional group including fluorine and carbon and suppresses formation of a third film. In the second film forming step, a third film is formed on the second film. In the first removal step, the surface of the substrate is irradiated with at least one of ions and an active species to remove the third film formed in the vicinity of the self-assembled monolayer. The third film is a film which forms a volatile compound more easily than the first film by being bonded to fluorine and carbon included in the self-assembled monolayer.

According to the present disclosure, it is possible to improve the productivity of semiconductor devices manufactured using selective film formation.

### BRIEF DESCRIPTION OF DRAWINGS

FIG. 1 is a schematic diagram showing an example of a film forming system according to an embodiment of the present disclosure.

FIG. 2 is a flowchart showing an example of a film formation method according to a first embodiment.

FIG. 3 is a cross-sectional view showing an example of a substrate prepared in a preparation step of the first embodiment.

FIG. 4 is a cross-sectional view showing an example of a substrate after a SAM is formed on a first film in the first embodiment.

FIG. 5 is a cross-sectional view showing an example of a substrate after a third film is formed on a second film in the first embodiment.

FIG. 6 is a schematic cross-sectional view showing an example of a plasma processing apparatus used in a first removal step.

FIG. 7 is a cross-sectional view showing an example of a substrate after nuclei of the third film on the SAM has been removed in the first embodiment.

FIG. 8 is a cross-sectional view showing an example of a substrate after the SAM on the first film has been removed in the first embodiment.

FIG. 9 is a flowchart showing an example of a film formation method according to a second embodiment.

FIG. 10 is a cross-sectional view showing an example of a substrate prepared in a preparation step of the second embodiment.

FIG. 11 is a cross-sectional view showing an example of a substrate after a SAM is formed on a metal wiring in the second embodiment.

FIG. 12 is a cross-sectional view showing an example of a substrate after a dielectric film is formed in the second embodiment.

FIG. 13 is a cross-sectional view showing an example of a substrate after the SAM has been removed in the second embodiment.

FIG. 14 is a cross-sectional view showing an example of a substrate after a SAM is further formed on a metal wiring in the second embodiment.

FIG. 15 is a cross-sectional view showing an example of a substrate after a dielectric film is further formed on the dielectric film in the second embodiment.

FIG. 16 is a cross-sectional view showing an example of a substrate after the SAM has been removed in the second embodiment.

FIG. 17 is a flowchart showing another example of the film formation method according to the second embodiment.

FIG. 18 is a flowchart showing a further example of the film formation method according to the second embodiment.

### DETAILED DESCRIPTION

Hereinafter, embodiments of the disclosed film formation method will be described in detail with reference to the drawings. The disclosed film formation method is not limited by the following embodiments.

In the conventional selective film formation, a substrate having a metal film and an insulating film exposed on the surface thereof is prepared, and a SAM for suppressing formation of an oxide film is formed on the metal film. Then, an oxide film is formed on the insulating film. At this time, the formation of the oxide film on the metal film is suppressed by the SAM. Therefore, the oxide film is not formed on the metal film.

However, since the ability of the SAM to suppress the formation of the oxide film is not perfect, the nuclei of the oxide film may grow on the SAM as well. As a result, if the formation of the oxide film is continued, the oxide film is also formed on the SAM. Therefore, it is necessary to remove the nuclei of the oxide film formed on the SAM when the formation of the oxide film on the insulating film has progressed to some extent. After the nuclei of the oxide film on the SAM are removed, the SAM is replenished on the metal film, and the oxide film is formed again on the insulating film. If the SAM remains on the metal film after the nuclei of the oxide film on the SAM are removed, the SAM remaining on the metal film is removed, the SAM is replenished on the metal film, and an oxide film is formed on the insulating film again. By repeating the formation of the oxide film, the removal of the nuclei on the SAM, and the replenishment of the SAM in this order, an oxide film having a desired thickness can be formed on the insulating film.

The nuclei of the oxide film formed on the SAM can be removed by, for example, etching that uses a fluorocarbon-based gas. However, since the fluorocarbon-based gas is supplied to the entire substrate, the oxide film formed on the insulating film is also etched, and the film thickness of the oxide film is reduced. Therefore, even if the formation of the oxide film, the removal of the nuclei on the SAM, and the replenishment of the SAM are repeated, the film thickness of the oxide film formed on the insulating film does not easily reach a desired film thickness. Accordingly, it is required to improve the productivity of the entire process for selectively forming an oxide film having a desired film thickness only on an insulating film.

Therefore, the present disclosure provides a technique capable of improving the productivity of a semiconductor device using selective film formation.

### First Embodiment

### [Film Forming System]

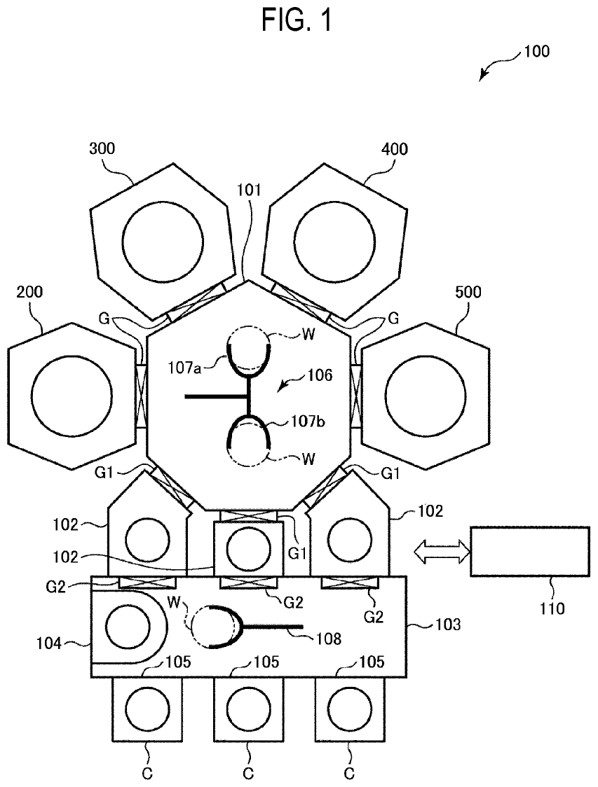

FIG. 1 is a schematic diagram showing an example of a film forming system 100 according to an embodiment of the present disclosure. The film forming system 100 includes a SAM supply apparatus 200, a film forming apparatus 300, a plasma processing apparatus 400, and a plasma processing apparatus 500. These apparatuses are connected to the four side walls of a vacuum transfer chamber 101 having a heptagonal plan-view shape via gate valves G, respectively. The film forming system 100 is a multi-chamber type vacuum processing system. The inside of the vacuum transfer chamber 101 is evacuated by a vacuum pump to maintain a predetermined degree of vacuum. The film forming system 100 selectively forms a third film on a second film of a substrate W having a first film and the second film exposed on the surface thereof by using the SAM supply apparatus 200, the film forming apparatus 300, the plasma processing apparatus 400, and the plasma processing apparatus 500.

The SAM supply apparatus 200 forms a SAM in a region of the first film of the substrate W by supplying a gas of an organic compound for forming the SAM to the surface of the substrate W. The SAM in the present embodiment has a function of adsorbing to the surface of the first film and suppressing the formation of the third film.

In the present embodiment, the organic compound for forming the SAM has functional groups including fluorine and carbon. The organic compound for forming the SAM is, for example, an organic compound that includes a bonding functional group adsorbed on the surface of the first film, a functioning functional group including fluorine and carbon, and an alkyl chain for connecting the bonding functional group and the functioning functional group.

When the first film is made of, for example, gold or copper, for example, a thiol-based compound represented by the general formula “R—SH” may be used as the organic compound for forming the SAM. In this regard, “R” includes a fluorine atom and a carbon atom. The thiol-based compound has the property of adsorbing on the surface of a metal such as gold or copper and not adsorbing on the surface of oxide or carbon. Examples of such a thiol-based compound include CF₃(CF₂)₁₅CH₂CH₂SH, CF₃(CF₂)₇CH₂CH₂SH, CF₃(CF₂)₅CH₂CH₂SH, HS—(CH₂)₁₁—O—(CH₂)₂—(CF₂)₅—CF₃, HS—(CH₂)₁₁—O—CH₂—C₆F₅, and the like.

When the first film is, for example, a silicon nitride film or the like, for example, an organic silane-based compound represented by the general formula “R—Si(OCH₃)₃” or “R—SiCl₃” may be used as the organic compound for forming the SAM. Further, when the first film is made of, for example, aluminum oxide or the like, for example, a phosphonic acid-based compound represented by the general formula “R—P(═O)(OH)₂” may be used as the organic compound for forming the SAM. In addition, when the first film is made of, for example, tantalum oxide, for example, an isocyanate-based compound represented by the general formula “R—N═C═O” may be used as the organic compound for forming the SAM.

In the present embodiment, the first film is a film on which the SAM is more easily adsorbed than the second film. Further, the third film is a film which forms a volatile compound more easily than the first film by being bonded to fluorine and carbon contained in the SAM. As the combinations of the materials of the first film, the second film, the third film and the SAM, for example, the combinations shown in Tables 1 to 4 below may be considered.

TABLE 1

| | First | Second | Third |
|---|---|---|---|
| SAM | film | film | film |
| Thiol-based | Copper | Silicon nitride film | Silicon |
| compound | Gold | Silicon oxide film | Silicon nitride film |
| | Silver | Aluminum oxide | Silicon oxide film |
| | Platinum | Hafnium oxide | Titanium nitride |
| | Palladium | Titanium nitride | Titanium oxide |
| | Iron | Titanium oxide | Tungsten oxide |
| | Nickel | Nickel oxide | Tantalum oxide |
| | Zinc | Chromium oxide | Spin-on carbon |
| | GaAs | Iron oxide | Ruthenium |
| | InP | Manganese oxide | Aluminum oxide |
| | GaN | Niobium oxide | Aluminum |
| | Silicon halide | Zirconium oxide | Titanium |
| | Ruthenium | Tungsten oxide | Tungsten |
| | | Tantalum oxide | |
| | | Silver oxide | |
| | | Copper oxide | |
| | | Tin oxide | |
| | | PZT | |
| | | ITO | |
| | | Spin-on carbon | |
| | | Aluminum | |
| | | Hafnium | |
| | | Titanium | |
| | | Chromium | |
| | | Manganese | |
| | | Niobium | |
| | | Zirconium | |
| | | Tungsten | |
| | | Tantalum nitride | |

TABLE 2

| | First | Second | Third |
|---|---|---|---|
| SAM | film | film | film |
| Organic silane- | Silicon nitride | Copper | Silicon |
| based compound | film | Gold | Silicon nitride |
| | Silicon oxide film | Silver | film |
| | Silicon halide | Platinum | Silicon oxide film |
| | Aluminum oxide | Palladium | Titanium nitride |
| | Hafnium oxide | Iron | Titanium oxide |
| | Titanium nitride | Nickel | Tungsten oxide |
| | Titanium oxide | Zinc | Tantalum oxide |
| | Nickel oxide | GaAs | Spin-on carbon |
| | Chromium oxide | InP | Ruthenium |
| | Iron oxide | GaN | Aluminum oxide |
| | Manganese oxide | Ruthenium | Aluminum |
| | Niobium oxide | Aluminum | Titanium |
| | Zirconium oxide | Hafnium | Tungsten |
| | Tungsten oxide | Titanium | |
| | Tantalum oxide | Chromium | |
| | Silver oxide | Manganese | |
| | Copper oxide | Niobium | |
| | Tin oxide | Zirconium | |
| | PZT | Tungsten | |
| | ITO | | |
| | Germanium oxide | | |
| | Spin-on carbon | | |
| | Ruthenium | | |

TABLE 3

| | First | Second | Third |
|---|---|---|---|
| SAM | film | film | film |
| Phosphonic acid- | Copper | Gold | Silicon |
| based compound | Silicon halide | Silver | Silicon nitride |
| | Aluminum oxide | Platinum | film |
| | Hafnium oxide | Palladium | Silicon oxide film |
| | Titanium oxide | Nickel | Titanium nitride |
| | Nickel oxide | Zinc | Titanium oxide |
| | Chromium oxide | GaAs | Tungsten oxide |
| | Iron oxide | InP | Tantalum oxide |
| | Manganese oxide | GaN | Spin-on carbon |
| | Niobium oxide | Silicon nitride | Ruthenium |
| | Zirconium oxide | film | Aluminum oxide |
| | Tungsten oxide | Silicon oxide | Aluminum |
| | Spin-on carbon | film | Titanium |
| | Ruthenium | | Tungsten |
| | Aluminum | | |
| | Hafnium | | |
| | Titanium | | |
| | Nickel | | |
| | Chromium | | |
| | Iron | | |
| | Manganese | | |
| | Niobium | | |
| | Zirconium | | |
| | Tungsten | | |

TABLE 4

| | First | Second | Third |
|---|---|---|---|
| SAM | film | film | film |
| Isocyanate-based | Silicon halide | Copper | Silicon |
| compound | Silicon oxide film | Gold | Silicon nitride |
| | Aluminum oxide | Silver | film |
| | Hafnium oxide | Platinum | Silicon oxide film |
| | Titanium oxide | Palladium | Titanium nitride |
| | Nickel oxide | Iron | Titanium oxide |
| | Chromium oxide | Nickel | Tungsten oxide |
| | Iron oxide | Zinc | Tantalum oxide |
| | Manganese oxide | GaAs | Spin-on carbon |
| | Niobium oxide | InP | Ruthenium |
| | Zirconium oxide | GaN | Aluminum oxide |
| | Tungsten oxide | PZT | Aluminum |
| | Tantalum oxide | Silicon nitride | Titanium |
| | Silver oxide | film | Tungsten |
| | Copper oxide | ITO | |
| | Tin oxide | Ruthenium | |
| | Spin-on carbon | Iron oxide | |
| | ITO | Aluminum | |
| | | Hafnium | |
| | | Titanium | |
| | | Chromium | |
| | | Manganese | |
| | | Niobium | |
| | | Zirconium | |
| | | Tungsten | |

In the combinations shown in Tables 1 to 4, it is assumed that the material of the first film and the material of the second film are different, and the material of the first film and the material of the third film are different.

The film forming apparatus 300 forms a third film on the second film of the substrate W on which the SAM is formed by the SAM supply apparatus 200. In the present embodiment, the film forming apparatus 300 forms a third film on the region of the second film of the substrate W by ALD (Atomic Layer Deposition) using the raw material gas and the reaction gas. As the raw material gas, for example, a gas such as silane chloride or dimethyl silane chloride may be used. As the reaction gas, for example, an H₂O gas or an N₂O gas may be used.

The plasma processing apparatus 400 irradiates at least one of ions and active species on the substrate W on which the third film is formed by the film forming apparatus 300. In the present embodiment, the plasma processing apparatus 400 irradiates the ions and the active species contained in the plasma on the substrate W by exposing the substrate W to plasma of a rare gas such as an Ar gas or the like. The plasma may be generated by using plural types of rare gases (e.g., a He gas and an Ar gas).

The plasma processing apparatus 500 removes the SAM remaining on the first film by further exposing the surface of the substrate W irradiated with the ions and the active species by the plasma processing apparatus 400 to plasma. In the present embodiment, the plasma processing apparatus 500 removes the SAM remaining on the first film by, for example, generating plasma of a hydrogen gas and exposing the surface of the substrate W to the plasma of the hydrogen gas. The plasma processing apparatus 500 may use plasma of another gas such as an oxygen gas to remove the SAM remaining on the first film. Further, the SAM remaining on the first film may be removed by using a highly reactive gas such as an ozone gas without using plasma.

Three load lock chambers 102 are connected to the other three side walls of the vacuum transfer chamber 101 via gate valves G1. An atmospheric transfer chamber 103 is provided on the opposite side of the vacuum transfer chamber 101 with the load lock chambers 102 interposed therebetween. The three load lock chambers 102 are respectively connected to the atmospheric transfer chamber 103 via gate valves G2. The load lock chambers 102 control the pressure between the atmospheric pressure and the vacuum when the substrate W is transferred between the atmospheric transfer chamber 103 and the vacuum transfer chamber 101.

Three ports 105 configured to mount carriers C (FOUP (Front-Opening Unified Pod) or the like) for accommodating substrates W are provided on the side surface of the atmospheric transfer chamber 103 opposite to the side surface where the gate valves G2 are provided. Further, an alignment chamber 104 for aligning the substrate W is provided on the side wall of the atmospheric transfer chamber 103. A downflow of clean air is formed in the atmospheric transfer chamber 103.

A transfer mechanism 106 such as a robot arm is provided in the vacuum transfer chamber 101. The transfer mechanism 106 transfers the substrate W between the SAM supply apparatus 200, the film forming apparatus 300, the plasma processing apparatus 400, the plasma processing apparatus 500, and each load lock chamber 102. The transfer mechanism 106 includes two independently movable arms 107a and 107b.

A transfer mechanism 108 such as a robot arm is provided in the atmospheric transfer chamber 103. The transfer mechanism 108 transfers the substrate W between each carrier C, each load lock chamber 102, and the alignment chamber 104.

The film forming system 100 includes a controller 110 having a memory, a processor, and an input/output interface. The memory stores a program executed by the processor and a recipe including a condition for each process. The processor executes a program read from the memory and controls each part of the film forming system 100 via the input/output interface based on the recipe stored in the memory.

[Film Formation Method]

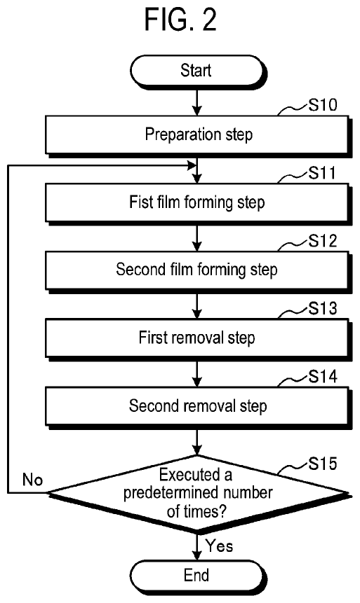

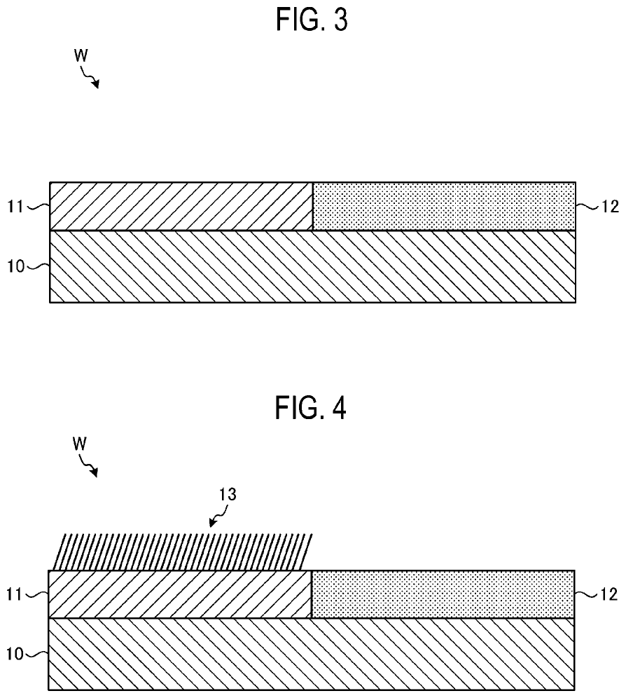

FIG. 2 is a flowchart showing an example of a film formation method according to a first embodiment. In the present embodiment, for example, a third film is selectively formed by the film forming system 100 shown in FIG. 1 on a second film of the substrate W having a surface from which a first film and a second film are exposed. The film formation method shown in the flowchart of FIG. 2 is realized by controlling each part of the film forming system 100 by the controller 110. Hereinafter, an example of the film formation method according to the first embodiment will be described with reference to FIGS. 3 to 8.

First, a preparation step is executed (S10). In the preparation step S10, as shown in FIG. 3, for example, a substrate W having a first film 11 and a second film 12 on a base material 10 is prepared. FIG. 3 is a cross-sectional view showing an example of the substrate W prepared in the preparation step of the first embodiment. In the present embodiment, the base material 10 is, for example, silicon, the first film 11 is a metal film such as copper or the like, and the second film 12 is an insulating film such as a silicon oxide film or the like.

The substrate W prepared in step S10 is accommodated in the carrier C and set in the port 105. Then, the substrate W is taken out from the carrier C by the transfer mechanism 108, passed through the alignment chamber 104, and then carried into one of the load lock chambers 102. Then, after the inside of the load lock chamber 102 is evacuated, the substrate W is carried out from the load lock chamber 102 by the transfer mechanism 106 and carried into the SAM supply apparatus 200.

Next, a first film forming step is executed (S11). In the first film forming step S11, a gas of an organic compound for forming a SAM is supplied into the SAM supply apparatus 200 into which the substrate W is loaded. The molecules of the organic compound supplied into the SAM supply apparatus 200 are not adsorbed on the surface of the second film 12 but adsorbed on the surface of the first film 11 of the substrate W to form a SAM on the first film 11. The main processing condition in the first film forming step S11 is, for example, as follows.

Substrate W temperature: 100 to 350 degrees C. (preferably 150 degrees C.)

Pressure: 1 to 100 Torr (preferably 50 Torr)

Organic compound gas flow rate: 50 to 500 sccm (preferably 250 sccm)

Processing time: 10 to 300 seconds (preferably 30 seconds)

As a result, the state of the substrate W becomes, for example, as shown in FIG. 4. FIG. 4 is a cross-sectional view showing an example of the substrate W after the SAM 13 is formed on the first film 11 in the first embodiment. After the processing of step S11 is executed, the substrate W is unloaded from the SAM supply apparatus 200 by the transfer mechanism 106 and loaded into the film forming apparatus 300.

Next, a second film forming step is executed (S12). In the second film forming step S12, a third film such as an oxide film is formed on the substrate W by ALD in the film forming apparatus 300 into which the substrate W is loaded. In the present embodiment, the third film formed on the substrate W by the ALD is, for example, a silicon oxide film. In the ALD, an ALD cycle including an adsorption step, a first purging step, a reaction step, and a second purging step is repeated a predetermined number of times.

In the adsorption step, a raw material gas such as a silane chloride gas is supplied into the film forming apparatus 300. As a result, the molecules of the raw material gas are chemically adsorbed on the surface of the second film 12. However, the molecules of the raw material gas are hardly adsorbed on the SAM 13. The main processing condition in the adsorption step is, for example, as follows.

Substrate W temperature: 100 to 350 degrees C. (preferably 200 degrees C.)

Pressure: 1 to 10 Torr (preferably 5 Torr)

Raw material gas flow rate: 10 to 500 sccm (preferably 250 sccm)

Processing time: 0.3 to 10 seconds (preferably 1 second)

In the first purging step, an inert gas such as a nitrogen gas is supplied into the film forming apparatus 300, whereby the molecules of the raw material gas excessively adsorbed on the second film 12 are removed. The main processing condition in the first purging step is, for example, as follows.

Substrate W temperature: 100 to 350 degrees C. (preferably 200 degrees C.)

Pressure: 1 to 10 Torr (preferably 5 Torr)

Inert gas flow rate: 500 to 5000 sccm (preferably 2000 sccm)

Processing time: 0.3 to 10 seconds (preferably 5 seconds)

In the reaction step, a reaction gas such as an H₂O gas is supplied into the film forming apparatus 300, and the molecules of the reaction gas react with the molecules of the raw material gas adsorbed on the second film 12 to form a silicon oxide film (third film 14) on the second film. At this time, since there are almost no molecules of the raw material gas on the SAM 13, the third film 14 is hardly formed on the SAM 13. The main processing condition in the reaction step is, for example, as follows.

Substrate W temperature: 100 to 350 degrees C. (preferably 200 degrees C.)

Pressure: 1 to 10 Torr (preferably 5 Torr)

Reaction gas flow rate: 100 to 2000 sccm (preferably 250 sccm)

Processing time: 0.3 to 10 seconds (preferably 1 second)

In the second purging step, an inert gas such as a nitrogen gas is supplied into the film forming apparatus 300, whereby the molecules of the unreacted raw material gas on the second film 12 are removed. The main processing condition in the second purging step is the same as the processing condition in the first purging step described above.

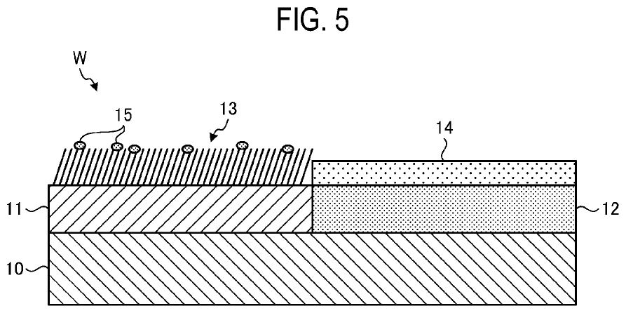

By repeating the ALD cycle including the adsorption step, the first purging step, the reaction step and the second purging step a predetermined number of times, a third film 14 is formed on the second film 12, for example, as shown in FIG. 5. FIG. 5 is a cross-sectional view showing an example of the substrate W after the third film 14 is formed in the first embodiment.

The region of the SAM 13 on the first film 11 is also exposed to the raw material gas and the reaction gas. Further, the ability of the SAM 13 to suppress the formation of the third film 14 is not perfect. Therefore, by repeating the ALD cycle, for example, as shown in FIG. 5, the nuclei 15 of the third film 14 may be formed on the SAM 13.

If the ALD cycle is repeated even after the nuclei 15 of the third film 14 are formed on the SAM 13, the nuclei 15 grow to eventually form a third film 14 on the SAM 13. In order to prevent this phenomenon, it is necessary to remove the nuclei 15 formed on the SAM 13 before the nuclei 15 grow on the third film 14. After the processing of step S12 is executed, the substrate W is unloaded from the film forming apparatus 300 by the transfer mechanism 106 and loaded into the plasma processing apparatus 400.

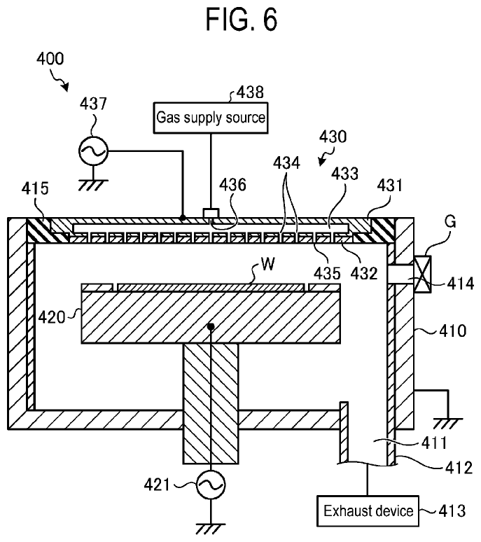

Next, a first removal step is executed (S13). The first removal step S13 is performed by, for example, the plasma processing apparatus 400 as shown in FIG. 6. FIG. 6 is a schematic cross-sectional view showing an example of the plasma processing apparatus 400 used in the first removal step. The plasma processing apparatus 400 according to the present embodiment is, for example, a capacitively coupled parallel plate plasma processing apparatus. The plasma processing apparatus 400 includes a processing container 410 having a surface made of, for example, anodized aluminum or the like, and having a substantially cylindrical space formed therein. The processing container 410 is grounded for security.

Inside the processing container 410, a stage 420 having a substantially cylindrical shape and configured to mount the substrate W thereon is provided. The stage 420 is made of, for example, aluminum or the like. A radio-frequency power source 421 is connected to the stage 420. The radio-frequency power source 421 supplies radio-frequency power of a predetermined frequency (e.g., 400 kHz to 13.5 MHz) used for implanting (biasing) ions to the stage 420.

An exhaust port 411 is provided at the bottom of the processing container 410. An exhaust device 413 is connected to the exhaust port 411 via an exhaust pipe 412. The exhaust device 413 includes a vacuum pump such as a turbo molecular pump and can reduce the pressure inside the processing container 410 to a desired degree of vacuum.

An opening 414 for loading and unloading the substrate W is formed on the side wall of the processing container 410. The opening 414 is opened and closed by a gate valve G.

A shower head 430 is provided above the stage 420 so as to face the stage 420. The shower head 430 is supported on an upper portion of the processing container 410 via an insulating member 415. The stage 420 and the shower head 430 are provided in the processing container 410 so as to be substantially parallel to each other.

The shower head 430 has a ceiling plate holding part 431 and a ceiling plate 432. The ceiling plate holding part 431 is formed of, for example, aluminum whose surface is anodized, and the ceiling plate 432 is detachably supported under the ceiling plate holding part 431.

A diffusion chamber 433 is formed in the ceiling plate holding part 431. An introduction port 436 communicating with the diffusion chamber 433 is formed in the upper portion of the ceiling plate holding part 431. Flow paths 434 communicating with the diffusion chamber 433 are formed in the bottom portion of the ceiling plate holding part 431. A gas supply source 438 is connected to the introduction port 436 via a pipe. The gas supply source 438 is a source of a rare gas such as an Ar gas or the like. The rare gas is an example of a processing gas.

The ceiling plate 432 has through-holes 435 that penetrates the ceiling plate 432 in the thickness direction. One through-hole 435 communicates with one flow path 434. The rare gas supplied from the gas supply source 438 into the diffusion chamber 433 via the introduction port 436 is diffused in the diffusion chamber 433 and is supplied into the processing container 410 via the flow paths 434 and the through-holes 435 in a shower-like manner.

A radio-frequency power source 437 is connected to the ceiling plate holding part 431 of the shower head 430. The radio-frequency power source 437 supplies radio-frequency power of a predetermined frequency used for generating plasma to the ceiling plate holding part 431. The frequency of the radio-frequency power used for generating plasma is, for example, a frequency in the range of 450 kHz to 2.5 GHz. The radio-frequency power supplied to the ceiling plate holding part 431 is radiated into the processing container 410 from the lower surface of the ceiling plate holding part 431. The rare gas supplied into the processing container 410 is turned into plasma by the radio-frequency power radiated to the processing container 410. Then, the active species contained in the plasma are irradiated on the surface of the substrate W. In addition, the ions contained in the plasma are implanted into the surface of the substrate W by the bias power supplied to the stage 420 from the radio-frequency power source 421 and are irradiated on the surface of the substrate W.

By irradiating the substrate W with at least one of the ions and the active species, the SAM 13 on the first film 11 is excited, and the fluorine and carbon contained in the SAM 13 react with the nuclei 15 of the third film 14 formed on the SAM 13. Then, the nuclei 15 of the third film 14 formed on the SAM 13 are converted into a volatile silicon fluoride compound and are removed from the SAM 13. The main processing condition in the first removal step S13 is, for example, as follows.

Substrate W temperature: 30 to 350 degrees C. (preferably 200 degrees C.)

Pressure: several mTorr to 100 Torr (preferably 10 mTorr)

Rare gas flow rate: 10 to 1000 sccm (preferably 100 sccm)

Radio-frequency power for plasma generation: 100 to 5000 W (preferably 2000 W)

Radio-frequency power for bias: 10 to 1000 W (preferably 100 W)

Processing time: 1 to 300 seconds (preferably 30 seconds)

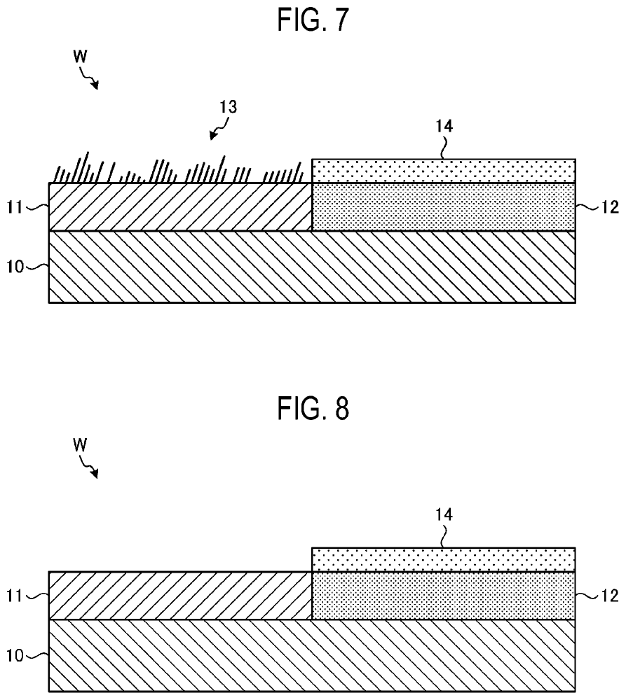

As a result, the state of the substrate W becomes, for example, as shown in FIG. 7. FIG. 7 is a cross-sectional view showing an example of the substrate W after the nuclei 15 of the third film 14 on the SAM 13 are removed in the first embodiment. When the surface of the substrate W is irradiated with at least one of the ions and the active species contained in the plasma, a part of the SAM 13 on the first film 11 is decomposed to react with the nuclei 15 of the third film 14 on the SAM 13, whereby the third film 14 on the SAM 13 is removed. On the other hand, even if the third film 14 is irradiated with at least one of the ions and the active species, the third film 14 is hardly scraped and the film thickness of the third film 14 is almost unchanged. After the processing of step S13 is executed, the substrate W is unloaded from the plasma processing apparatus 400 by the transfer mechanism 106 and loaded into the plasma processing apparatus 500.

Next, a second removal step is executed (S14). In the second removal step S14, for example, plasma of a hydrogen gas is generated in the plasma processing apparatus 500 into which the substrate W is loaded. As the plasma processing apparatus 500, for example, an apparatus having the same structure as the plasma processing apparatus 400 described with reference to FIG. 6 may be used. The main processing condition in the second removal step S14 is, for example, as follows.

Substrate W temperature: 30 to 350 degrees C. (preferably 200 degrees C.)

Pressure: several mTorr to 100 Torr (preferably 50 Torr)

Hydrogen gas flow rate: 10 to 1000 sccm (preferably 200 sccm)

Radio-frequency power for plasma generation: 100 to 5000 W (preferably 2000 W)

Radio-frequency power for bias: 10 to 1000 W (preferably 100 W)

Processing time: 1 to 300 seconds (preferably 30 seconds)

As a result, the entire SAM 13 remaining on the first film 11 is removed, and the state of the substrate W becomes, for example, as shown in FIG. 8. FIG. 8 is a cross-sectional view showing an example of the substrate W after the SAM 13 on the first film 11 is removed in the first embodiment.

Next, it is determined whether the processes of steps S11 to S14 are executed a predetermined number of times (S15). The predetermined number of times is the number of times by which the processes of steps S11 to S14 are repeated until the third film 14 having a predetermined thickness is formed on the second film 12. If steps S11 to S14 are not executed a predetermined number of times (S15: No), the process shown in step S11 is executed again.

On the other hand, when steps S11 to S14 are executed a predetermined number of times (S15: Yes), the substrate W is unloaded from the plasma processing apparatus 500 by the transfer mechanism 106 and loaded into one of the load lock chambers 102. Then, after the inside of the load lock chamber 102 is returned to the atmospheric pressure, the substrate W is unloaded from the load lock chamber 102 by the transfer mechanism 108 and returned to the carrier C. Thus, the film formation method shown in this flowchart is completed.

In this regard, if the nuclei 15 of the third film 14 formed on the SAM 13 are removed by dry etching using a fluorocarbon-based gas, the nuclei 15 are removed, but the third film 14 formed on the second film 12 is also etched. Therefore, it takes a long time to form the third film 14 having a predetermined thickness on the second film 12. This makes it difficult to improve the productivity of semiconductor devices manufactured using the substrate W.

On the other hand, in the present embodiment, in step S11, the SAM 13 containing fluorine and carbon is selectively formed on the first film 11, and in step S13, at least one of the ions and the active species is irradiated on the entire substrate W. As a result, the SAM 13 on the first film 11 is decomposed, and the nuclei 15 of the third film 14 on the SAM 13 are removed as a volatile silicon fluoride compound by the fluorine and carbon contained in the SAM 13.

On the other hand, since the third film 14 formed on the second film 12 has almost no fluorine atom and carbon atom, the third film 14 is hardly etched even when it is irradiated with at least one of the ions and the active species. Therefore, the third film 14 having a predetermined thickness can be formed on the second film 12 at an early stage, and the productivity of semiconductor devices manufactured using the substrate W can be improved.

The first embodiment has been described above. As described above, the film formation method according to the present embodiment, which is a film formation method for selectively forming a film on the substrate W, includes a preparation step, a first film forming step, a second film forming step, and a first removal step. In the preparation step, the substrate W having a surface on which the first film 11 and the second film 12 are exposed is prepared. In the first film forming step, a compound for forming a self-assembled monolayer which has a functional group including fluorine and carbon and suppresses formation of a third film 14 is supplied onto the substrate W, whereby a SAM 13 is formed on the first film 11. In the second film forming step, a third film 14 is formed on the second film 12. In the first removal step, the surface of the substrate W is irradiated with at least one of ions and an active species to remove the third film 14 formed in the vicinity of the SAM 13. The third film 14 is a film forms a volatile compound more easily than the first film 11 by being bonded to fluorine and carbon contained in the SAM 13. This makes it possible to improve the productivity of semiconductor devices manufactured using the selective film formation.

Further, in the first removal step of the above-described embodiment, the surface of the substrate W is irradiated with at least one of the ions and the active species, whereby the nuclei 15 of the third film 14 formed on the SAM 13 are removed. This makes it possible to improve the productivity of semiconductor devices manufactured using the selective film formation.

Further, the film formation method according to the above-described embodiment further includes a second removal step of removing the SAM 13 formed on the first film 11, which is executed after the first removal step. The first film forming step, the second film forming step, the first removal step, and the second removal step are repeated plural times in this order. As a result, a third film 14 having a desired thickness can be quickly formed on the second film 12 by selective film formation.

Further, in the first removal step of the above-described embodiment, the surface of the substrate W is exposed to plasma of a processing gas, whereby at least one of the ions and the active species contained in the plasma is irradiated on the surface of the substrate W. The processing gas is, for example, a rare gas. This makes it possible to efficiently irradiate the surface of the substrate W with at least one of the ions and the active species.

Further, in the above-described embodiment, the first film 11 may be, for example, a metal film, the second film 12 may be, for example, an insulating film, and the third film 14 may be, for example, an oxide film. As a result, a third film 14 having a desired thickness can be quickly formed on the second film 12 by selective film formation.

Further, in the above-described embodiment, the organic compound for forming the SAM 13 is an organic compound having a bonding functional group adsorbed on the surface of the first film 11 and a functioning functional group including fluorine and carbon. Specifically, the organic compound for forming the SAM 13 is, for example, a thiol-based compound, an organic silane-based compound, a phosphonic acid-based compound, or an isocyanato-based compound. As a result, the SAM 13 can be selectively formed on the surface of the first film 11.

### Second Embodiment

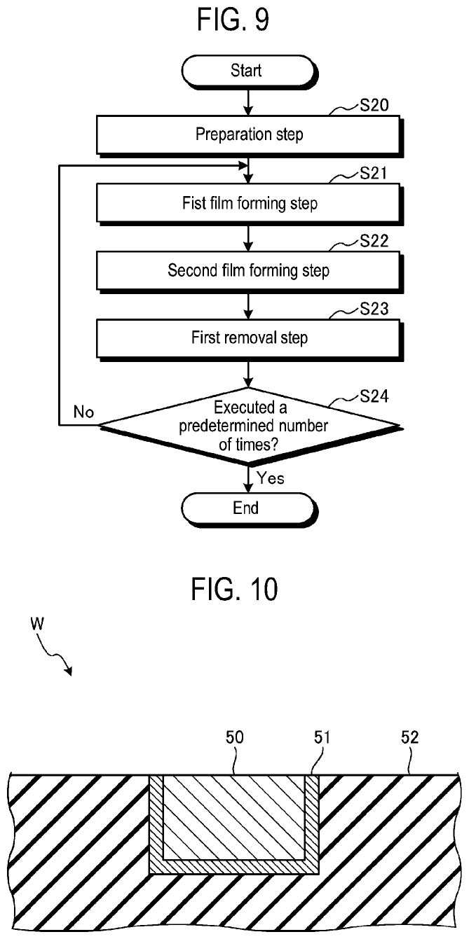

FIG. 9 is a flowchart showing an example of a film formation method according to the second embodiment. In the present embodiment, a third film is selectively formed by the film forming system 100 shown in FIG. 1 on a second film of a substrate W having a surface from which a first film and the second film are exposed. The film formation method shown in the flowchart of FIG. 9 is realized by controlling each part of the film forming system 100 by the controller 110. Hereinafter, an example of the film formation method according to the second embodiment will be described with reference to FIGS. 10 to 16. The plasma processing apparatus 500 is not used in the film formation method according to the present embodiment.

First, a preparation step is executed (S20). In the preparation step S20, for example, as shown in FIG. 10, a substrate W in which a barrier film 51 and a metal wiring 50 are embedded in a groove of an interlayer insulating film 52 made of a low-k material is prepared. FIG. 10 is a cross-sectional view showing an example of the substrate W prepared in the preparation step of the second embodiment. The metal wiring 50 is an example of the first film, and the barrier film 51 and the interlayer insulating film 52 are examples of the second film. In the present embodiment, the metal wiring 50 is made of, for example, copper, the barrier film 51 is made of, for example, tantalum nitride, and the interlayer insulating film 52 is, for example, a silicon oxide film.

The substrate W prepared in step S20 is accommodated in the carrier C and set in the port 105. Then, the substrate W is taken out from the carrier C by the transfer mechanism 108, passed through the alignment chamber 104, and then loaded into one of the load lock chambers 102. Then, after the inside of the load lock chamber 102 is evacuated, the substrate W is unloaded from the load lock chamber 102 by the transfer mechanism 106 and loaded into the SAM supply apparatus 200.

Next, a first film forming step is executed (S21). In the first film forming step S21, a gas of an organic compound for forming a SAM is supplied into the SAM supply apparatus 200 into which the substrate W is loaded. As the organic compound for forming the SAM, for example, a thiol-based compound having a functional group including a carbon atom and a fluorine atom may be used. The molecules of the organic compound supplied into the SAM supply apparatus 200 are not adsorbed to the surfaces of the barrier film 51 and the interlayer insulating film 52 of the substrate W but are adsorbed to the surface of the metal wiring 50 to form a SAM on the metal wiring 50. The main processing condition in the first film forming step S21 is the same as the main processing condition in the first film forming step S11 of the first embodiment.

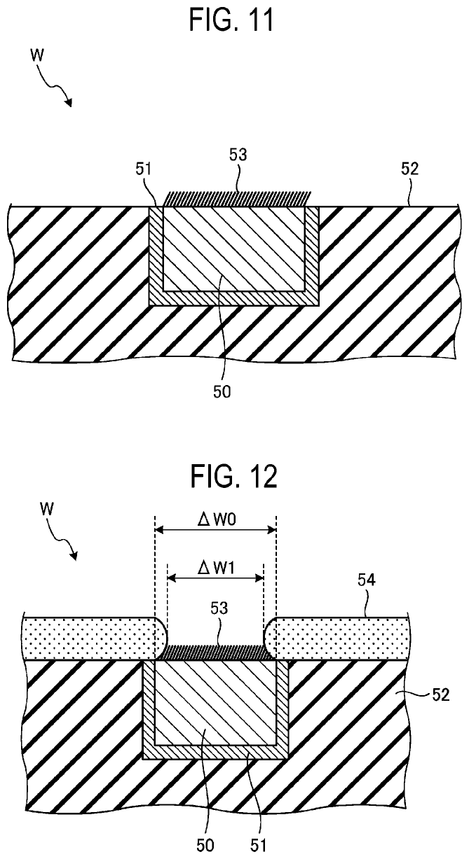

As a result, the state of the substrate W becomes, for example, as shown in FIG. 11. FIG. 11 is a cross-sectional view showing an example of the substrate W after the SAM 53 is formed on the metal wiring 50 in the second embodiment. After the processing of step S21 is executed, the substrate W is unloaded from the SAM supply apparatus 200 by the transfer mechanism 106 and loaded into the film forming apparatus 300.

Next, a second film forming step is executed (S22). In the second film forming step S22, a dielectric film 54 is formed on the substrate W by ALD in the film forming apparatus 300 into which the substrate W is loaded. The dielectric film 54 is an example of a third film. In the present embodiment, the dielectric film 54 is, for example, aluminum oxide. In the ALD, an ALD cycle including an adsorption step, a first purging step, a reaction step, and a second purging step is repeated a predetermined number of times.

In the adsorption step, a raw material gas such as a TMA (trimethylaluminum) gas is supplied into the film forming apparatus 300. As a result, the molecules of the raw material gas are chemically adsorbed on the surfaces of the barrier film 51 and the interlayer insulating film 52. However, the molecules of the raw material gas are hardly adsorbed on the SAM 53. The main processing condition in the adsorption step is, for example, as follows.

Substrate W temperature: 80 to 250 degrees C. (preferably 150 degrees C.)

Pressure: 0.1 to 10 Torr (preferably 3 Torr)

Raw material gas flow rate: 1 to 300 sccm (preferably 50 sccm)

Processing time: 0.1 to 5 seconds (preferably 0.2 seconds)

In the first purging step, the molecules of the raw material gas excessively adsorbed on the barrier film 51 and the interlayer insulating film 52 are removed by supplying a rare gas such as an argon gas or an inert gas such as a nitrogen gas into the film forming apparatus 300. The main processing condition in the first purging step is, for example, as follows.

Substrate W temperature: 80 to 250 degrees C. (preferably 150 degrees C.)

Pressure: 0.1 to 10 Torr (preferably 3 Torr)

Inert gas flow rate: 5 to 15 slm (preferably 10 slm)

Processing time: 0.1 to 15 seconds (preferably 2 seconds)

In the reaction step, a reaction gas such as an H₂O gas is supplied into the film forming apparatus 300, and the molecules of the reaction gas react with the molecules of the raw material gas adsorbed on the barrier film 51 and the interlayer insulating film 52 to form an aluminum oxide film (dielectric film 54) on the barrier film 51 and the interlayer insulating film 52. At this time, since there are almost no molecules of the raw material gas on the SAM 53, the dielectric film 54 is hardly formed on the SAM 53. The main processing condition in the reaction step is, for example, as follows.

Substrate W temperature: 80 to 250 degrees C. (preferably 150 degrees C.)

Pressure: 0.1 to 10 Torr (preferably 3 Torr)

Reaction gas flow rate: 10 to 500 sccm (preferably 100 sccm)

Processing time: 0.1 to 5 seconds (preferably 0.5 seconds)

In the second purging step, a rare gas such as an argon gas or an inert gas such as a nitrogen gas is supplied into the film forming apparatus 300, whereby the molecules of the unreacted raw material gas on the substrate W are removed. The main processing condition in the second purging step is the same as the processing condition in the first purging step described above.

By repeating the ALD cycle including the adsorption step, the first purging step, the reaction step and the second purging step a predetermined number of times, a dielectric film 54 is formed on the barrier film 51 and the interlayer insulating film 52, for example, as shown in FIG. 12. FIG. 12 is a cross-sectional view showing an example of the substrate W after the dielectric film 54 is formed in the second embodiment.

In this regard, the region of the SAM 53 on the metal wiring 50 is also exposed to the raw material gas and the reaction gas. Further, the ability of the SAM 53 to suppress the formation of the dielectric film 54 is not perfect. Therefore, by repeating the above ALD cycle, nuclei of the dielectric film 54 may be formed on the SAM 53, for example, as shown in FIG. 5. Further, in the process of growing the dielectric film 54 by repeating the ALD cycle, the dielectric film 54 also grows in the lateral direction. As shown in FIG. 12, for example, a part of the dielectric film 54 protrudes into the region of the metal wiring 50. As a result, the width of the opening of the dielectric film 54 becomes a width ΔW1 narrower than the width ΔW0 of the region of the metal wiring 50.

Next, a first removal step is executed (S23). The first removal step S23 is performed by, for example, the plasma processing apparatus 400 as shown in FIG. 6. The plasma processing apparatus 400 of the present embodiment may not be provided with a radio-frequency power source 421. In the first removal step, the processing gas is turned into plasma, and at least one of the ions and the active species contained in the plasma is irradiated on the substrate W. As a result, the SAM 53 on the metal wiring 50 is excited, the fluorine and carbon contained in the SAM 53 react with the nuclei of the dielectric film 54 formed on the SAM 53, and the nuclei of the dielectric film 54 is removed as a volatile fluorine compound from the SAM 53.

Further, by irradiating at least one of the ions and the active species contained in the plasma on the substrate W, the SAM 53 adjacent to the dielectric film 54 is excited, and the active species having fluorine and carbon contained in the SAM 53 are generated. Then, the active species having fluorine and carbon react with the side portion of the dielectric film 54 adjacent to the SAM 53. As a result, the side portion of the dielectric film 54 protruding into the region of the metal wiring 50 is removed as a volatile fluorine compound or a volatile compound containing fluorine and carbon.

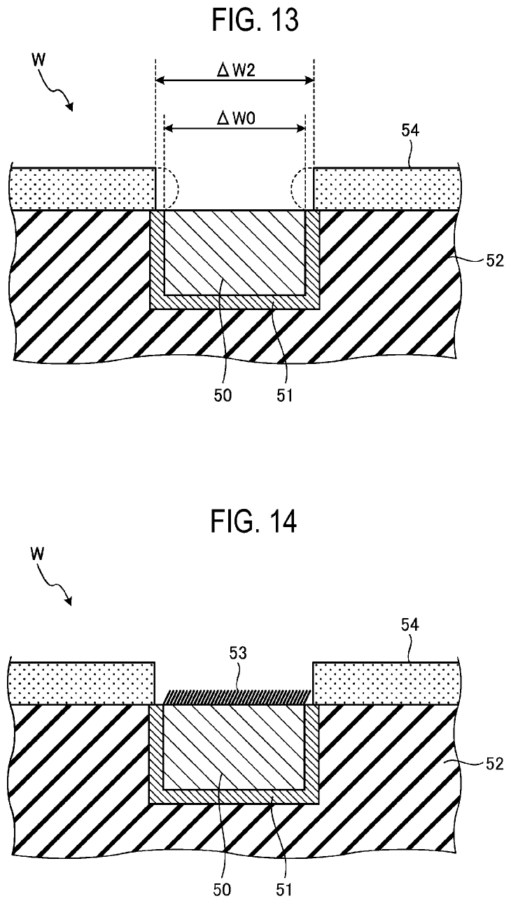

As a result, for example, as shown in FIG. 13, the width of the opening of the dielectric film 54 is widened to a width ΔW2 larger than the width ΔW0 of the region of the metal wiring 50. FIG. 13 is a cross-sectional view showing an example of the substrate W after the SAM 53 is removed in the second embodiment. As a result, when a via hole connected to the metal wiring 50 is formed in the opening of the dielectric film 54 in the subsequent step, the width of the via hole can be made larger than the width of the metal wiring 50, which makes it possible to suppress an increase in resistance value of the via hole. Since the active species generated by the excitation of the SAM 53 have a short lifetime, they are inactivated before reaching the upper surface of the dielectric film 54. Therefore, the upper surface of the dielectric film 54 is hardly etched by the active species generated by the excitation of the SAM 53.

In the present embodiment, the processing gas used in step S23 is, for example, a hydrogen gas. As the processing gas, in addition to the hydrogen gas, a gas containing at least one of an ammonia gas, a hydrazine gas, and a hydrocarbon gas such as methane may be used as long as it is a hydrogen-containing gas. By executing step S23, the SAM 53 on the metal wiring 50 is removed. Therefore, in the present embodiment, the second removal step for the purpose of removing the SAM 53 is not executed.

The main processing condition in the first removal step S23 is, for example, as follows.

Substrate W temperature: 50 to 300 degrees C. (preferably 150 degrees C.)

Pressure: 0.1 Torr to 50 Torr (preferably 2 Torr)

Processing gas flow rate: 200 to 3000 sccm (preferably 1000 sccm)

Radio-frequency power for plasma generation: 50 to 1000 W (preferably 200 W)

Processing time: 1 to 60 seconds (preferably 10 seconds)

Next, it is determined whether the processes of steps S21 to S23 have been executed a predetermined number of times (S24). The predetermined number of times is the number of times by which the processes of steps S21 to S23 are repeated until the dielectric film 54 having a predetermined thickness is formed on the interlayer insulating film 52. When steps S21 to S23 have not been executed a predetermined number of times (S24: No), the process of step S21 is executed again, whereby a SAM 53 is formed on the surface of the metal wiring 50, for example, as shown in FIG. 14.

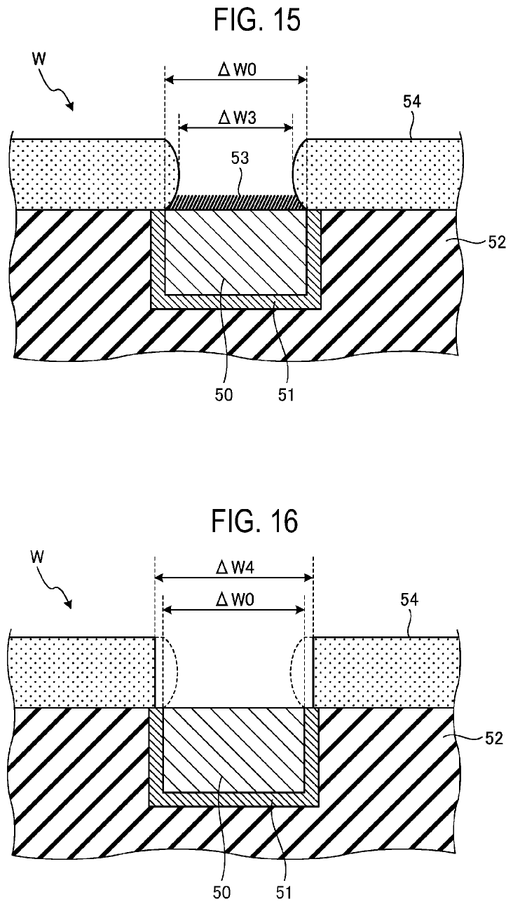

Then, by executing the process of step S22 again, a dielectric film 54 is further formed on the barrier film 51 and the dielectric film 54. As a result, for example, as shown in FIG. 15, a part of the dielectric film 54 protrudes again into the region of the metal wiring 50, and the width of the opening of the dielectric film 54 becomes a width ΔW3 smaller than the width ΔW0 of the region of the metal wiring 50.

Then, by executing the process of step S23 again, the nuclei of the dielectric film 54 on the SAM 53 and the side portion of the dielectric film 54 protruding into the region of the metal wiring 50 are removed by the active species including fluorine and carbon contained in the SAM 53. As a result, for example, as shown in FIG. 16, the width of the opening of the dielectric film 54 is widened to a width ΔW4 larger than the width ΔW0 of the region of the metal wiring 50.

By repeating steps S21 to S23 in this way, the dielectric film 54 having an arbitrary thickness can be formed around the metal wiring 50 while maintaining the width of the opening of the dielectric film 54 larger than the width ΔW0 of the region of the metal wiring 50.

The second embodiment has been described above. In the first removal step of the present embodiment, the surface of the substrate W is irradiated with at least one of the ions and the active species, whereby the side portion of the dielectric film 54 adjacent to the SAM 53 is removed. Thus, the width of the opening of the dielectric film 54 can be made larger than the width of the region of the metal wiring 50.

Further, in the first removal step of the present embodiment, the surface of the substrate W is exposed to the plasma of the processing gas, whereby at least one of the ions and the active species contained in the plasma is irradiated on the surface of the substrate W. The processing gas is, for example, a hydrogen-containing gas. This makes it possible to efficiently irradiate the surface of the substrate W with at least one of the ions and the active species.

### [Others]

The technique disclosed in the subject application is not limited to the above-described embodiment, and many modifications may be made within the scope of the gist thereof.

For example, in the above-mentioned first embodiment, the third film 14 is formed by ALD in the second film forming step S12. However, the disclosed technique is not limited thereto. As another example, in the second film forming step S12, the third film 14 may be formed by CVD (Chemical Vapor Deposition).

Further, in the above-mentioned first embodiment, in the first removal step S13, the substrate W is exposed to the plasma of the rare gas to irradiate the surface of the substrate W with the ions contained in the plasma. However, the disclosed technique is not limited thereto. For example, the surface of the substrate W may be irradiated with ions using a focused ion beam device or the like.

Further, in the first embodiment described above, the film forming system 100 is provided with one SAM supply apparatus 200, one film forming apparatus 300, one plasma processing apparatus 400, and one plasma processing apparatus 500. However, the disclosed technique is not limited thereto. For example, the plasma processing apparatus 400 and the plasma processing apparatus 500 may be realized by one plasma processing apparatus. Further, for example, the film forming system 100 may be provided with plural apparatuses for performing the most time-consuming process. Each of other processes may be performed by one apparatus. For example, when the process of step S11 takes a long time, plural SAM supply apparatuses 200 for performing the process of step S11 may be provided, and one apparatus for performing each of the processes of S12 to S14 may be provided. As a result, it is possible to reduce the process waiting time when processing plural substrates W.

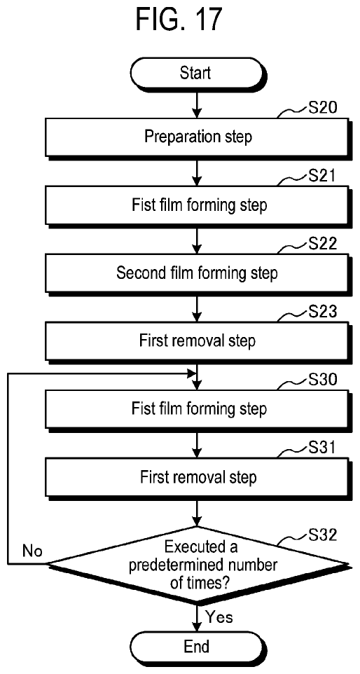

Further, in the second embodiment described above, the first film forming step, the second film forming step and the first removal step are repeatedly executed in this order. However, the disclosed technique is limited thereto. For example, as shown in FIG. 17, after the first film forming step (S21), the second film forming step (S22) and the first removal step (S23) are executed, the first film forming step (S30) and the first removal step (S31) may be performed one or more times in this order. FIG. 17 is a flowchart showing another example of the film formation method according to the second embodiment. The process performed in the first film forming step S30 is the same as the process performed in the first film forming step S21, and the process performed in the first removal step S31 is the same as the process performed in the first removal step S23. In the film formation method shown in FIG. 17, the dielectric film 54 having a sufficient thickness is formed in the second film forming step S22. Then, by repeating the first film forming step S30 and the first removal step S31, the width of the opening of the dielectric film 54 can be made larger than the width of the region of the metal wiring 50.

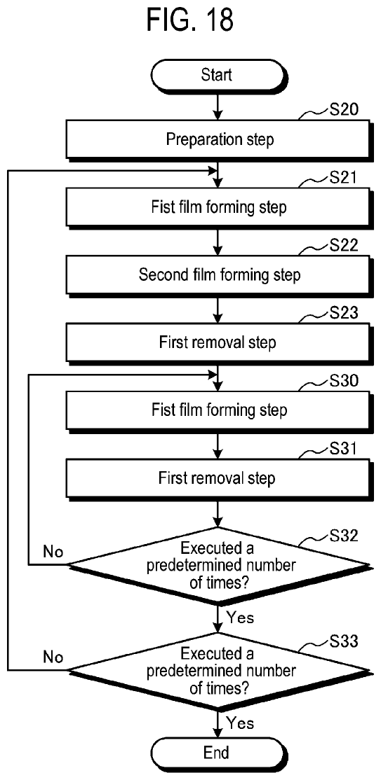

Further, for example, as shown in FIG. 18, a process (S33) for determining whether the processes of S21 to S23 and the processes of S30 to S32 have been repeated a predetermined number of times may be executed. As a result, it is possible to prevent the thickness of the dielectric film 54 from becoming too large in step S22 and prevent the opening of the dielectric film 54 from being blocked.

Further, the processing gas used in the first removal step of the second embodiment described above is a hydrogen-containing gas. However, the disclosed technique is not limited thereto. For example, the processing gas may include a rare gas such as an argon gas in addition to the hydrogen-containing gas.

It should be noted that the embodiments disclosed herein are exemplary in all respects and are not limitative. Indeed, the above-described embodiments can be embodied in a variety of forms. Moreover, the above-described embodiments may be omitted, replaced, or changed in various forms without departing from the scope of the appended claims and the spirit thereof.

### EXPLANATION OF REFERENCE NUMERALS

C: carrier, G: gate valve, W: substrate, 10: base material, 11: first film, 12: second film, 13: SAM, 14: third film, 15: nuclei, 100: film forming system, 101 vacuum transfer chamber, 102: load lock chamber, 103: atmospheric transfer chamber, 104: alignment chamber, 105: port, 106: transfer mechanism, 107: arm, 108: transfer mechanism, 110: controller, 200: SAM supply apparatus, 300: film forming apparatus, 400: plasma processing apparatus, 410: processing container, 411: exhaust port, 412: exhaust pipe, 413: exhaust device, 414: opening, 415: insulating member, 420: stage, 421: radio-frequency power source, 430: shower head, 431: ceiling plate holding part, 432: ceiling plate, 433: diffusion chamber, 434: flow path, 435: through-hole, 436: introduction port, 437: radio-frequency power source, 438: gas supply source, 500: plasma processing apparatus, 50: metal wiring, 51: barrier film, 52: interlayer insulating film, 53: SAM, 54: dielectric film

1-11. (canceled)

12. A film formation method for selectively forming a film on a substrate, comprising:
a preparation step of preparing a substrate having a surface on which a first film and a second film are exposed;
a first film forming step of supplying a compound for forming a self-assembled monolayer onto the substrate to form the self-assembled monolayer on the first film, the compound having a functional group including fluorine and carbon and suppressing formation of a third film;
a second film forming step of forming the third film on the second film; and
a first removal step of removing the third film formed in a vicinity of the self-assembled monolayer by irradiating the surface of the substrate with at least one of ions and active species,
wherein the third film is a film which forms a volatile compound more easily than the first film by being bonded to fluorine and carbon included in the self-assembled monolayer.

13. The method of claim 12, wherein in the first removal step, the surface of the substrate is irradiated with at least one of the ions and the active species to remove nuclei of the third film formed on the self-assembled monolayer.

14. The method of claim 13, wherein the first film forming step, the second film forming step and the first removal step are repeated plural times in this order.

15. The method of claim 14, wherein in the first removal step, the surface of the substrate is exposed to plasma of a processing gas so that at least one of ions and active species included in the plasma is irradiated on the surface of the substrate.

16. The method of claim 15, wherein the processing gas includes at least one of a rare gas and a hydrogen-containing gas.

17. The method of claim 16, wherein the first film is a metal film, the second film is an insulating film, and the third film is an oxide film.

18. The method of claim 17, wherein the compound for forming the self-assembled monolayer has a bonding functional group adsorbed on a surface of the first film and a functioning functional group including fluorine and carbon.

19. The method of claim 18, wherein the compound for forming the self-assembled monolayer is a thiol-based compound, an organic silane-based compound, a phosphonic acid-based compound, or an isocyanato-based compound.

20. The method of claim 12, wherein in the first removal step, the surface of the substrate is irradiated with at least one of the ions and the active species to remove a side portion of the third film adjacent to the self-assembled monolayer.

21. The method of claim 20, wherein after the first film forming step, the second film forming step and the first removal step are executed, and the first film forming step and the first removal step are performed once or more in this order.

22. The method of claim 12, wherein the first film forming step, the second film forming step and the first removal step are repeated plural times in this order.

23. The method of claim 12, further comprising:
a second removal step of removing the self-assembled monolayer on the first film, which is performed after the first removal step,
wherein the first film forming step, the second film forming step, the first removal step and the second removal step are repeated plural times in this order.

24. The method of claim 12, wherein in the first removal step, the surface of the substrate is exposed to plasma of a processing gas so that at least one of ions and active species included in the plasma is irradiated on the surface of the substrate.

25. The method of claim 24, wherein the processing gas includes at least one of a rare gas and a hydrogen-containing gas.

26. The method of claim 12, wherein the first film is a metal film, the second film is an insulating film, and the third film is an oxide film.

27. The method of claim 12, wherein the compound for forming the self-assembled monolayer has a bonding functional group adsorbed on a surface of the first film and a functioning functional group including fluorine and carbon.

28. The method of claim 27, wherein the compound for forming the self-assembled monolayer is a thiol-based compound, an organic silane-based compound, a phosphonic acid-based compound, or an isocyanato-based compound
